(19) United States
(12) Patent Application Publication
(10) Pub. No.: US 2015/0025761 A1
(43) Pub. Date: Jan. 22, 2015

(54) MAGNETIC FIELD SENSOR, ACTUATING DEVICE AND METHOD FOR DETERMINING A RELATIVE POSITION

(71) Applicant: ZF FRIEDRICHSHAFEN AG, FRIEDRICHSHAFEN (DE)

(72) Inventor: Bernd Kernebeck, Bad Essen (DE)

(21) Appl. No.: 14/380,903

(22) PCT Filed: Feb. 1, 2013
(86) PCT No.: PCT/EP2013/052013

§ 371 Date: Aug. 25, 2014

(30) Foreign Application Priority Data
Mar. 22, 2012 (DE) 10 2012 204 634.8

(51) Int. Cl. G01B 7/00; F16H 61/02; G01R 33/02

(52) U.S. Cl. CPC G01B 7/003; G01R 33/02; F16H 61/0213
USPC 701/60; 324/207.11

(57) ABSTRACT

A magnetic field sensor consists of a transmitter device for producing a magnetic field and a detecting device for detecting the magnetic field. The transmitter device and the detecting device are arranged in such a way that they can move in relation to each other. The detecting device consists of a first sensor for producing a first sensor signal which is dependent on the magnetic field and a second sensor for producing a second sensor signal which is dependent on the magnetic field. The first sensor and the second sensor are arranged next to each other within the extension of a longitudinal axis of a detection range of a magnet in the transmitter device.

The present disclosure relates to a magnetic field sensor, an operating device for a vehicle as well as a procedure for the determination of a relative position between a first component and a second component, which can be used for example in connection with a gear selector lever of a vehicle.

Magnetic field sensors can be used for the determination of a relative position between two components. For this, a transmitter device, by means of which a magnetic field is produced, can be arranged on a first component and a detecting device for the evaluation of the magnetic field can be arranged on a second component.

EP 1 777 501 A1 describes a position sensor arrangement for a contactless position determination by means of redundant magnetically sensitive sensor elements.

In this context, the present disclosure presents an improved magnetic field sensor, an improved operating device for a vehicle as well as an improved procedure for the determination of a relative position between a first component and a second component according to the main claims. Advantageous embodiments can be derived from the dependent claims and from the following description.

In a magnetic field sensor that can be used for the determination of a position, a magnetic field is produced by a transmitter device and is detected by means of a detecting device which can be moved in relation to the transmitter device. When the transmitter device and the detecting device move relative towards each other, this results a variation of the magnetic field, which is detected by the detecting device. By means of a size of the magnetic field that is detected by the detecting device, it is possible to determine a relative position between the transmitter device and the detecting device. The magnetic field sensor can be influenced by a magnetic interference field. In order to detect and eliminate the influence of such an interference field in a subsequent signal evaluation, it is possible that the sensor unit consists of at least two sensors. The two sensors can be arranged and aligned in such a way that they are influenced in the same manner by means of the interference field. If sensor signals are combined with each other in a proper way, it is possible to determine the contained proportion of the interference field within the sensor signals and to eliminate it. By means of this it is possible to use the magnetic field sensor in cases where variations in the interference field are to be expected.

Advantageously, such a position detection can be accomplished by means of analog sensors, which are insensitive to external interference. Such an approach can be used, for example, for a three dimensional sensor. A three dimensional sensor can be used, for example, for the determination of a position or alignment of a gear selector lever of a vehicle.

The present disclosure relates to a magnetic field sensor with a transmitter device consisting of at least one magnet for producing a magnetic field and a detecting device for detecting the magnetic field, where the transmitter device and the detecting device are arranged in such a way that they can move in relation towards each other and where the detecting device consists of a first sensor for producing a first sensor signal which is dependent on the magnetic field and a second sensor for producing a second sensor signal which is dependent on the magnetic field, characterized in that the first sensor and the second sensor are arranged next to each other within the extension of a longitudinal axis of a detection range of the at least one magnet.

The magnetic field sensor thus consists of a transmitter device and a detecting device, which are arranged separately from each other and which can be moved in relation towards each other. The transmitter device can consist of one or more magnets or magnet elements, each in form of a permanent magnet or of an electromagnet. The magnet or magnets can be constructed as rod magnets. It is also possible to use an air-core coil or a solenoid as a magnet element. The longitudinal axis of a magnet can be defined by means of the direction of the longitudinal extension of the magnet or of the core of the magnet, or in the case of an air-coil or solenoid by means of a direction of the longitudinal extension of the air core. The magnetic field lines, which come out of a magnetic pole or out of the magnetic poles of the magnet, can be aligned parallel to the longitudinal axis. The longitudinal axis can be aligned in a home position or in a center position of the magnetic field sensor, orthogonal to a scanning level of the first sensor and of the second sensor. The center position can be one of a number of possible relative positions between the transmitter device and the detecting device. In the center position, the magnetic field lines of the magnetic field within the detection range can run orthogonally towards the scanning level of the first sensor and the scanning level of the second sensor. The sensors can feature further scanning levels, which are aligned orthogonally towards the previously mentioned scanning levels. Thus, the sensors can be designed as one dimensional, as two dimensional or as three dimensional sensors. The sensors can be common sensors for measuring the magnetic flux density. Such sensors could be, for example, hall effect sensors, XMR sensors (X-MagnetoResistive) or field plate sensors. The first sensor signal and the second sensor signal can be a respective electric signal, for example, an electrical voltage. The first sensor signal can represent the value of the proportion of the magnet field that was detected by the first sensor and the second sensor signal can represent the value of the proportion of the magnetic field that was detected by the second sensor. Thus, a change of a direction of the magnetic field can lead to a corresponding change of the first sensor signal and of the second sensor signal. The size of the detection range, in which the first sensor and the second sensor are arranged, can be selected in such a way that there is a predictable magnetic interference field for the operating range of the magnetic field sensor, which is homogeneous or almost homogeneous within the detection range, so that the first sensor and the second sensor are influenced by the same magnetic interference field. In this way it is possible that a magnetic interference field with almost equal strength and direction can issue onto the first sensor and onto the second sensor at the same time respectively. The expression “almost the same” can mean, for example, to be within the measuring tolerance of the magnetic field sensor.

The magnetic field sensor can consist of an evaluation device that is designed to combine the first sensor signal and the second sensor signal with each other in order to determine a superimposed magnetic disturbance and additionally or alternatively a parameter of the magnetic field and additionally or alternatively a relative position between the transmitter device and the detecting device. The evaluation device can be an electric circuit, which is designed to detect the sensor signals, to evaluate them and to provide an evaluation signal, which represents the magnetic disturbance, the parameter of the magnetic field or the relative position. In order to combine the sensor signals or the represented values of the sensor signals, the evaluation device can be designed in order to add or to subtract the sensor signals, or to produce an average value of the sensor signals. For example, it is possible that the evaluation device is designed in such a way that it can determine a value and additionally or alternatively a direction of the magnetic disturbance within the detection range. Further, it is possible that the evaluation device is designed in such a way that it can determine a value and additionally or alternatively a direction of the magnetic field within the detection range. When the value and additionally or alternatively a direction of the magnetic field is determined, any influence of the magnetic disturbance can be taken into account and can be eliminated or reduced. It is further possible that the evaluation device is arranged in such a way that it can determine the relative position between the transmitter device and the detecting device by using reference values as well as the value and additionally or alternatively a direction of the magnetic field. By means of combining the sensor signals, it is possible to detect the influence of the magnetic interference field on the sensor function and to further or alternatively reduce or eliminate it.

According to an embodiment, the first sensor and the second sensor are arranged in such a way, that the magnetic field which penetrates the first sensor during operation of the magnetic field sensors has a different magnetic field device than the magnetic field which penetrates the second sensor. The first and the second sensor are preferably arranged in such a way that during operation of the magnetic field sensor one of the two sensors is penetrated by a magnetic field that is coming from the magnetic north pole, and the other one of the two sensors by a magnetic field which is leading to a magnetic south pole, whereby the magnetic north- and south pole can be allocated to the at least one magnet or to two magnets.

The transmitter device can be designed to produce a first magnetic field and a second magnetic field. Hereby it is possible that the first magnetic field and the second magnetic field are aligned in opposite direction towards each other. The first sensor can be designed to produce the first sensor signal dependent on the first magnetic field. The second sensor can be designed to produce the second sensor signal dependent on the second magnetic field. The first sensor and the second sensor can be designed identically. The first and the second sensor can be aligned corresponding to each other and can be connected or electrically contacted. Hereby a scanning direction or scanning characteristic of the first sensor can correspond to a scanning direction or scanning characteristic of the second sensor. This means that an imaginary magnetic field of any kind can produce the same sensor signal when it influences the first sensor as it does when influencing the second sensor. It is possible for example, that base surfaces or contacting surfaces of the sensors are aligned in the same way. According to this embodiment, two magnetic fields are produced, wherein one of the magnetic fields is detected by the first sensor and the other one of the magnetic fields by the second sensor. One sensor is thus designated for each magnetic field. Since the first magnetic field and the second magnetic field can be aligned in opposite direction towards each other, a potential magnetic disturbance can lead to an amplification of the detected magnetic field in one of the sensors, and to a reduction of the detected magnetic field in the other one of the sensors. The first sensor can be aligned opposite to or within a main sphere of a magnetic north pole of the transmitter device. The second sensor can be aligned opposite to or within a main sphere of a magnetic south pole of the transmitter device. The magnetic north pole and the magnetic south pole can be arranged next to each other. A main expansion level of the magnetic north pole can be parallel to a main expansion level of the magnetic south pole. Magnetic field lines that come out of the magnetic north pole can run parallel to the magnetic field lines that enter into the magnetic south pole. During operation of the magnet field sensor it is possible that the magnetic field lines of the magnetic field that penetrate the first sensor run almost parallel to the magnetic field lines of the magnetic field that penetrate the second sensor. Within the designated possible relative positions that can be reached between the transmitter device and the detecting device during the operation of the magnetic field sensor, it is possible that field lines of the first magnetic field enter in the same angle into a scanning level of the first sensor respectively, as the field lines of the second magnetic field that come out of a scanning level of the second sensor. According to one embodiment, the respective angles can have the same values, but with a different sign. The term scanning level is to be understood as an area which is penetrated by a magnetic field which is to be detected or scanned by means of the sensor. A two dimensional sensor may consist of two scanning levels and a three dimensional sensor may consist of three scanning levels, which are aligned orthogonally towards each other respectively. A distance between a north pole of the transmitter device and the first sensor can have the same respective distance as between a south pole of the transmitter device and the second sensor within the designated possible relative positions between the transmitter device and the detecting device. The first sensor and the second sensor can be arranged in the same level, for example on a surface of a carrier, next to each other. Since the first magnetic field is aligned opposite to the second magnetic field, it is possible that the first sensor signal and the second sensor signal or the values that are represented by the first and the second sensor signal have different signs when there is no magnetic interference field.

Herein the transmitter device can consist of a first magnet for producing the first magnetic field and a second magnet, which is arranged next to the first magnet, for producing the second magnetic field. The first magnet can be designed identically to the second magnet. At least in a center position of the magnetic field sensor, the first magnet can be aligned parallel to the second magnet. According to one embodiment, it is possible that the first magnet is aligned parallel to the second magnet in all of the designated possible relative positions. A distance between a north pole of the first magnet and the first sensor can be the same distance as between a south pole of the second magnet and the second sensor respectively, within the designated possible relative positions between the transmitter device and the detecting device. The north pole of the first magnet can be aligned at an offset from the south pole of the second magnet. The first magnet and the second magnet can be designed as rod magnets respectively. The longitudinal axis of a magnet can be defined by means of the respective axis between the north pole and the south pole of the magnet. A first axis between the north pole and the south pole of the first magnet can be aligned parallel to a second axis between the north pole and the south pole of the second magnet. In all or in some of the designated possible relative positions between the transmitter device and the detecting device, the first axis can be aligned in such a way that it runs through the first sensor. The second axis can be aligned in such a way that it runs through the second sensor in all or in some of the designated possible relative positions between the transmitter device and the detecting device. The first axis and the second axis can be aligned parallel towards each other in the designated possible relative positions respectively. Alternatively it is possible that the first axis and the second axis incline in opposite directions after leaving a center position. According to this embodiment, the transmitter device can be achieved by means of two magnets.

Alternatively, it is possible that the at least one magnet has a magnetic north pole for producing a first magnetic field and a magnetic south pole for producing the second magnetic field. Herein, the first magnetic field and the second magnetic field can be sections of the magnet's magnetic field that are located between the magnetic north pole and the magnetic south pole. The magnet can, for example, be in the form of a U-shaped magnet, such as a horseshoe magnet. The magnet can consist of two longitudinal axes, which correspond to one direction of the longitudinal extension of one pole shank respectively. Aside from the fact that only one magnet is arranged for producing a first and a second magnetic field, it is possible that the construction and the mode of operation of this embodiment can correspond to the construction and mode of operation of an embodiment with two magnets.

According to an embodiment, the sizes of the first magnetic field and of the second magnetic field can be equal in their amount. This can be true in particular for the detection range. Magnetic fields of the same size can be accomplished if two identical magnets or one magnet with two identical shanks is used. Since the first magnetic field is aligned opposite to the second magnetic field, it is possible that the first sensor signal and the second sensor signal, or the values that represent the first sensor signal and the second sensor signal, can have a different sign and yet the same amount when there is an absence of a magnetic interference field. Due to the fact that the sizes of the magnetic fields are equal in their amount, it is easy to determine a magnetic interference field by means of the sensor signals.

The first sensor and the second sensor can be arranged next to each other in one scanning level. The scanning level can be formed by a surface of a circuit board. The circuit board can consist of electric wires for connecting the first and the second sensor.

According to an embodiment, the scanning direction of the first sensor can be aligned in the opposite direction of the scanning direction of the second sensor. During operation of the magnetic field sensor, a magnetic field line of the magnetic field can penetrate the first sensor as well as the second sensor. The first sensor and the second sensor can be arranged in a stacked order. For example, the first sensor can be arranged on a first surface of a carrier, e.g. a circuit board, and the second sensor can be arranged on a second surface which is located on the opposite side of the first surface of the carrier. The transmitter device can consist of one single magnet for producing the magnetic field. A distance from the north pole of the magnet, or alternatively from the south pole of the magnet, to the first sensor and to the second sensor, within the designated possible relative positions between the transmitter device and the detecting device, may only be differentiated by means of the distance between the first sensor and the second sensor. The magnet can be designed in form of a rod magnet. The longitudinal axis between the north pole and the south pole of the magnet can be directed through the first sensor and through the second sensor in all or some of the designated possible relative positions between the transmitter device and the detecting device. During operation of the magnet field sensor it is possible that the magnetic field lines of the magnetic field that penetrate the first sensor run almost parallel to the magnetic field lines of the magnetic field that penetrate the second sensor.

An operating device for a vehicle features the following characteristics:

a first component;

a second component, whereby the first component and the second component are arranged in such a way, that they can move in relation towards each other; and

a magnetic field sensor, wherein the transmitter device of the magnetic field sensor is arranged onto the first component and the detecting device of the magnetic field sensor is arranged onto the second component.

The vehicle may be a motor vehicle, such as an automobile or a truck. The operating device can be a device for selecting the gears in a manual transmission or for selecting the driving modes in an automatic transmission. For example, one of the components may be a selector lever. The other component may be the mounting or the host structure for the selector lever. The magnetic field sensor can be allocated within the area of a bearing, for example a ball joint or a cardan joint between the first component and the second component. By means of an evaluation of one or several signals of the magnetic field sensor, it is possible to determine the relative position between the components.

A procedure for the determination of a relative position between a first component and a second component, which are arranged in a way that they can move in relation to each other, comprises of the following steps:

production of a magnetic field with a transmitter device which is arranged on the first component, with at least one magnet for producing the magnetic field;

detection of the magnetic field with a detecting device which is arranged on the second component, consisting of a first sensor for producing a first sensor signal which is dependent on the magnetic field and a second sensor for producing a second sensor signal which is dependent on the magnetic field, whereby the first sensor and the second sensor are arranged next to each other within the extension of a longitudinal axis of a detection range of the at least one magnet; and

combining the first sensor signal with that of the second sensor signal, in order to determine the relative position between the first component and the second component.

The disclosure is further exemplified by means of the attached drawings. It is depicted:

FIG. 1—a schematic depiction of an operating device;

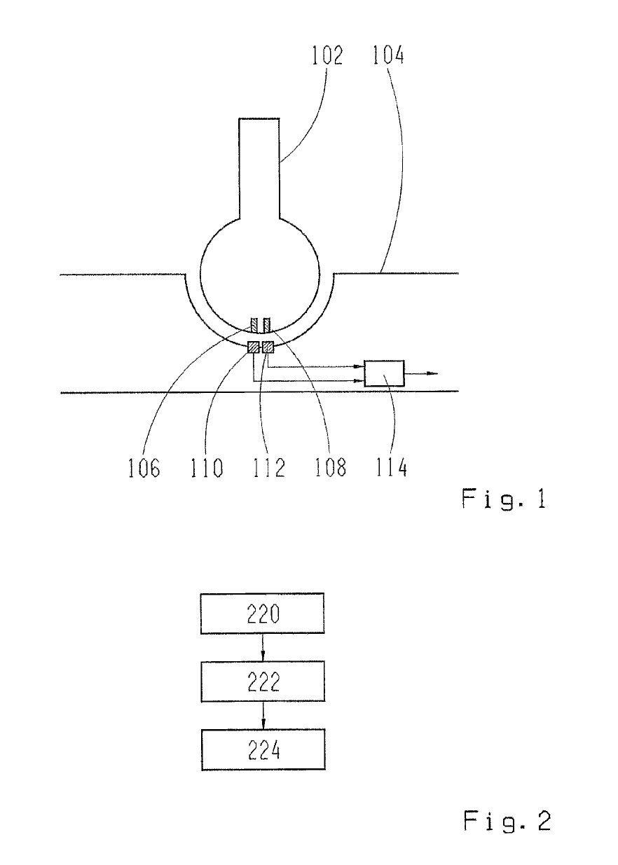

FIG. 2—a flow diagram of a procedure for the determination of a relative position;

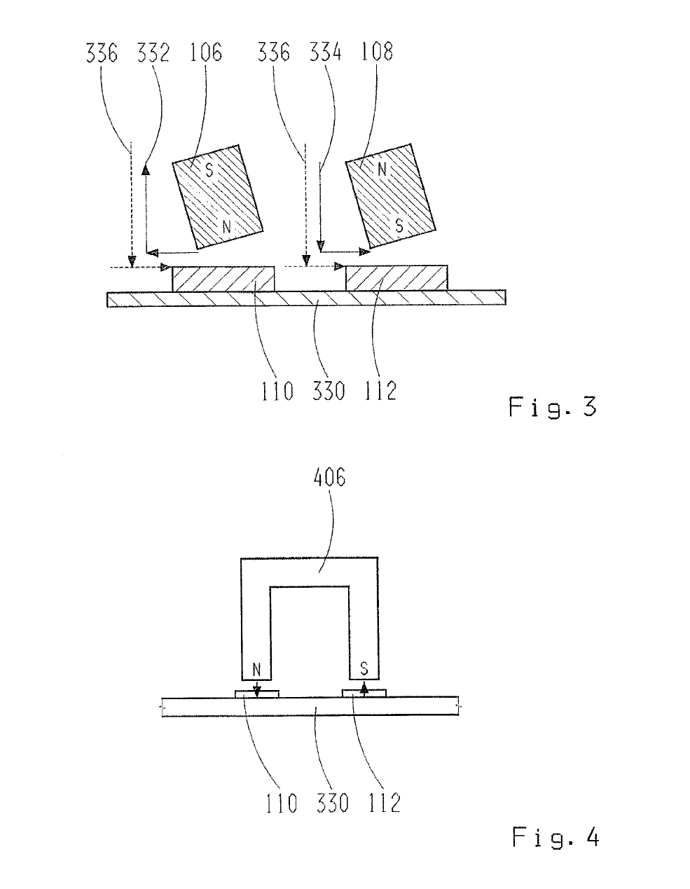

FIG. 3—a schematic depiction of a magnetic field sensor;

FIG. 4—a schematic depiction of a further magnetic field sensor;

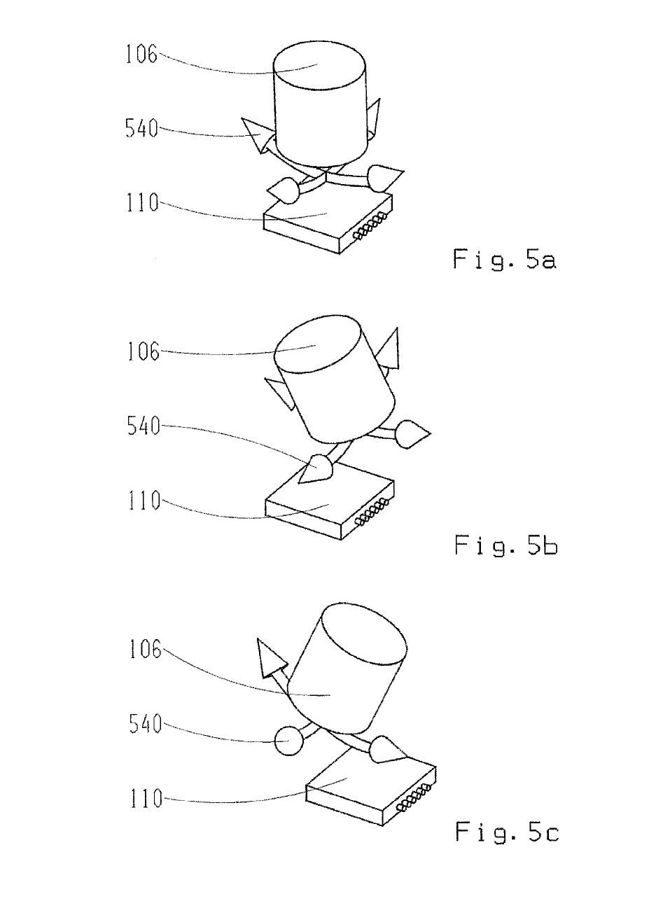

FIGS. 5a to 5c—schematic depiction of one portion of a magnetic field sensor in different relative positions; and

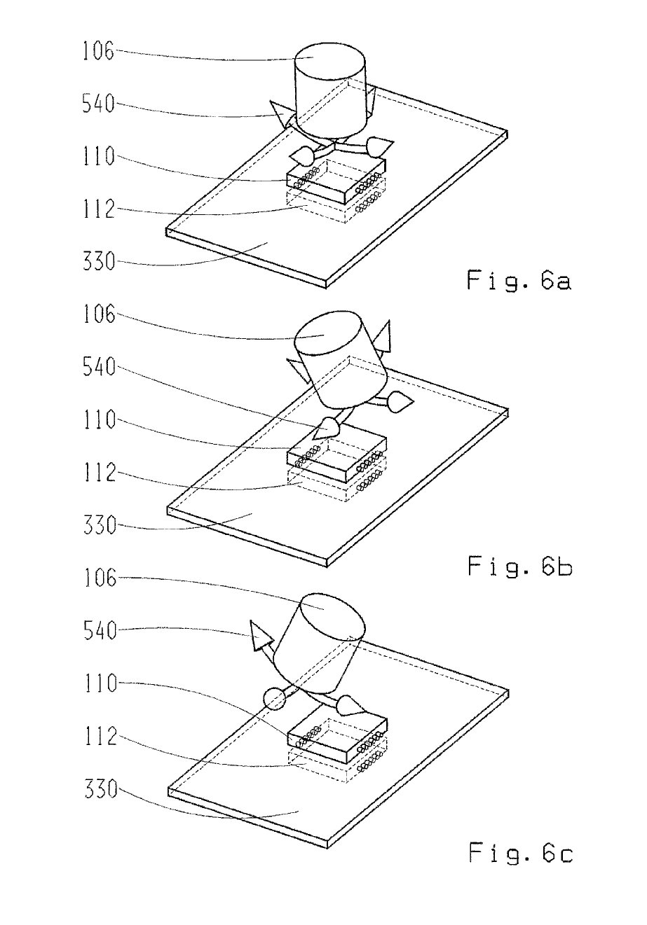

FIGS. 6a to 6c—schematic depiction of a magnetic field sensor in different relative positions.

In the following description of embodiments, the elements which are depicted in the different figures and which appear to be similar are described with the same or with similar reference signs, whereby a repeated description of these elements is omitted.

FIG. 1 shows a schematic depiction of an operating device according to an embodiment. The operating device features a first component 102 and a second component 104. The first component 102 and the second component are arranged flexibly towards each other, so that the first component 102 can perform a relative movement in relation to the second component 104.

The relative movement between the first component 102 and the second component 104 as well as a current relative position between the first component 102 and the second component 104 can be detected by means of a magnetic field sensor. The magnetic field sensor consists of a transmitter device and a detecting device. According to this embodiment, the transmitter device is mounted onto the first component 102 and the detecting device onto the second component 104. Alternatively, the detecting device is mounted onto the first component 102 and the transmitter device onto the second component 104. In this way, the transmitter device and the detecting device perform a corresponding movement, when there is any relative motion between the first and the second component 102, 104. Thus, it is possible to transmit a current relative position and a relative movement between the transmitter device and the detecting device to a current relative position and a relative movement between the first component 102 and the second component 104.

According to this embodiment, the transmitter device consist of a first magnet 106 and a second magnet 108. According to this embodiment, the detecting device consists of a first sensor 110 for detecting the magnetic field of the first magnet 106 and a second sensor 112 for detecting the magnetic field of the second magnet 108. In FIG. 1, the magnetic field sensor is depicted in a center position, in which the first sensor 110 is located directly opposite to a magnetic pole of the first magnet 106 and the second sensor 112 directly opposite to a magnetic pole of the second magnet 108.

According to an embodiment, the operating device can be a device for selecting a gear of a transmission in a vehicle. Thus, the first component 102 can be a selector lever, which can be operated by a driver of the vehicle, in order to select a certain gear. The first component 102 and the second component 104 can be connected to each other by means of a ball joint. The magnets 106, 108 can be arranged on the joint head of the ball joint.

The first sensor 110 is designed to transmit a first sensor signal, which represents a detected magnetic field that is made up of an overlapping of the magnetic field of the first magnet and a possibly existing magnetic interference field. Depending on the embodiment, the first sensor signal consists of a value of the strength of the detected magnetic field and additionally or alternatively a value for the direction of the detected magnetic field. The second sensor 112 is designed to transmit a second sensor signal, which represents a detected magnetic field that is made up of an overlapping of the magnetic field of the second magnet and the possibly existing magnetic interference field. Depending on the embodiment, the second sensor signal consists of a value of the strength of the detected magnetic field and additionally or alternatively a value for the direction of the detected magnetic field.

The evaluation device 114 is designed to detect and to evaluate the first sensor signal of the first sensor 110 and the second sensor signal of the second sensor 112. To accomplish this, the evaluation device 114 can be connected to the sensors 110, 112 by means of electric wires. The evaluation device 114 is designed to combine the first sensor signal and the second sensor signal with each other, in order to determine and to provide a relative position between the transmitter device and the detecting device, and thus a relative position between the first component 102 and the second component 104. The evaluation device 114 is therefore designed to determine the relative position, independent of any size and direction of the possibly existing magnetic influence field. For this, the evaluation device 114 can be designed to first of all determine the proportion of the magnetic influence field, and to take this into account in the subsequent determination of the relative position. Alternatively, the evaluation device 114 can be designed to determine the relative position directly, for which the proportion of the magnetic influence field is eliminated while the relative position is determined by means of a suitable combination of the first sensor signal and of the second sensor signal.

FIG. 2 depicts a flow diagram of a procedure for the determination of a relative position according to an embodiment. By means of this procedure, it is possible to determine, for example, a relative position between the components of an operating device, as it is depicted in FIG. 1.

In a step 220, a magnetic field is produced by means of a transmitter device. The magnetic field can be produced permanently or for a certain period of time, such as for the duration of a measuring cycle. In a step 222, the magnetic field is detected with a detecting device. The detecting device is arranged in a way that it can be moved in relation to the transmitter device. The detecting device consists of two separate sensors for detecting the magnetic field, which present a sensor signal respectively, by means of which the magnetic field is represented. In a step 224, the sensor signals are combined with each other in order to determine the relative position of the transmitter device and of the detecting device, and thus, for example, between the first component and the second component of the operating device.

FIG. 3 shows a schematic depiction of a magnetic field sensor according to an embodiment. The magnetic field sensor can be used, for example, in connection with the operating device as it is shown in FIG. 1.

The magnetic field sensor consists of a first magnet 106, a second magnet 108, a first sensor 110 and a second sensor 112. The first sensor 110 and the second sensor 112 are arranged next to each other on a surface of a carrier 330, for example a conductor board or a circuit board. But sensors 110, 112 do not have to be mounted on a carrier, like a circuit board. Sensors 110, 112 can also be mounted directly on a surface or the inside of the component as it is depicted in FIG. 1.

The first magnet 106 and the second magnet 108 are connected in such a way that they can be moved solidly or synchronously with each other, and can be moved together relative to sensors 110, 112.

The first magnet 106 is arranged opposite to the first sensor 110. A pole of the first magnet 106, in this case the north pole, is arranged opposite to a scanning surface of the first sensor 110. Magnet 106 is designed in order to produce a first magnetic field 332, which is detected by the first sensor 110. The magnetic field that is detected by the first sensor 110 is dependent on the position of the first magnet 106 in relation to the first sensor 110. In this way, a relative position between the first sensor 110 and the first magnet 106 can be determined by means of the detected magnetic field of the first sensor 110. Thus, the first magnet 106 and the first sensor 110 form a first measuring unit.

The second magnet 108 is arranged opposite to the second sensor 112. A pole of the second magnet 108, in this case the south pole, is arranged opposite to a scanning surface of the second sensor 112. The second magnet 108 is designed in order to produce a second magnetic field 334, which is detected by the second sensor 112. The magnetic field that is detected by the second sensor 112 is dependent on the position of the second magnet 108 in relation to the second sensor 112. In this way, a relative position between the second sensor 112 and the second magnet 108 can be determined by means of the detected magnetic field of the first sensor 112. Thus, the second magnet 108 and the second sensor 112 form a second measuring unit.

The first magnet 106 and the second magnet 108 are arranged in such a way that they are aligned in opposite direction with regard to their magnetic poles. In FIG. 3, magnets 106, 108 are depicted in a position in which they are tilted around a swivel axis.

Sensors 110, 112 are arranged within a detection range, which can be influenced by a magnetic influence field 336. The detection range can be selected so small that the magnetic influence field of the detection range is almost homogeneous, so that sensors 110, 112 are influenced by the same magnetic influence field 336. The existence and size of any magnetic influence field 336 may be unknown.

The first magnetic field 332 and the second magnetic field 334 are depicted with direction vectors (Sx) and the magnetic influence field is depicted with direction vectors (St).

The first magnetic field 332 is overlapped by the magnetic influence field 336. The second magnetic field 334 is also overlapped by the magnetic influence field 336. The first magnetic field 332 is aligned in opposite direction to the second magnetic field 334. The sizes of magnetic fields 332, 334 are equal in their amount. The magnetic field lines that are produced by means of the magnetic fields 332, 334, which run through magnets 106, 108 within the detection range, are aligned almost parallel towards each other. Magnetic fields 332, 334 both consist of a vertical component in a vertical direction which is orthogonal to the surface of carrier 330, and a horizontal component which is parallel to the surface of carrier 330. The vertical component and the horizontal component of the magnetic fields 332, 334 have a different sign respectively, which means that they are opposite to each other. The magnetic influence field consists of a vertical component, which is aligned in opposite direction to the vertical component of the first magnetic field 332, and a horizontal component, which is aligned in opposite direction of the first magnetic field 332. Thus, the first magnetic field 332 is weakened by the magnetic influence field 336 and the second magnetic field 334 is amplified by the magnetic influence field 336.

Magnets 106, 108 can be arranged as rod magnets. Magnets 106, 108 can be mounted to a component in such a way, that they can be moved relative to carrier 330. Magnets 106, 108 can be mounted to a component in such a way that magnets 106, 108 are moved synchronously when there is a motion of the component. Alternatively, it is possible that magnets 106, 108 are mounted to the component in such a way, that magnets 106, 108 are moved in the opposite direction to each other in a movement of the component, so that for example the first magnet 106 is moved in the same direction with the motion of the component, but the second magnet 108 is moved in the opposite direction. To accomplish this, magnets 106, 108 can be connected to the component by means of a suitable transmission unit.

In the following, an embodiment for eliminating the influence field in analog hall sensor systems is described by means of FIG. 3. Accordingly, sensors 110, 112 can be hall sensors.

A position detection by means of analog sensors 110, 112 is sensitive to external influence fields. It is possible for example, to determine the position of magnet 106 in X-, Y- and Z-direction by means of a 3D-sensor 110 and a magnet 106 (permanent or electric) which is arranged in a way that it can be moved in relation to it. Magnet 106 is, for example, mounted on the component, which can be part of a mechanical unit whose position is to be determined. But if the hall sensor 106 is now influenced by means of another magnetic field 336 (permanent or electric), by means of this influence field 336, it is no longer possible to determine the position of magnet 106.

In order to assure a correct position determination, sensor systems are often designed in a double, triple, fourfold, or n-fold way. In this way, a failure of a sensor 106 can be detected, and possibly be corrected, depending on the design of the system. Such additional sensors are not depicted in the figures.

The system, which is described by means of the figures in various embodiments is sensitive to the influence of interference from external magnetic fields 336, which can be permanent or electric in nature.

Such a sensor system, as it is, for example, depicted in FIG. 3 consists of at least two analog sensors 110, 112. The design of the system is chosen in such a way, that both sensors 110, 112 are used for the determination of the position, but that they also detect the size and direction of relevant influence fields 336. Thus, the influence field 336 can be eliminated by means of a correction calculation. The correction calculation can be performed, for example, in a controller, which can be discreetly digital (TIL) as well as analog (operational amplifier). A corresponding correction calculation can be performed, for example, in the evaluation device that is depicted in FIG. 1.

According to one embodiment, the determination of the vector of the disturbance of the influence field 336 is performed according to the following formula:

$$( \frac{{\overline{S}}_{1} + {\overline{S}}_{2}}{2} ) = {\overline{S}}_{t}$$

S̅ₜ: vector of the disturbance of the influence field 336
S̅₁: vector of the magnetic field detected by the first sensor 110
S̅₂: vector of the magnetic field detected by the second sensor 112

Accordingly, the determination of the position is performed with an adjustment of the redundancy or a validation of the plausibility by means of the following formula:

| S̅₁− S̅ₜ|=| S̅₂− S̅ₜ|

The underlying functional principle will be described in the following:

Two identical hall sensors 110, 112 are allocated to two magnets 106, 108 with opposite poles, which can be permanent or electrical magnets. The magnets 106, 108 are mechanically connected in such a way, that they perform the same movement at a change of position, or a movement which is connected to each other, for example in the opposite direction or with a transmission ratio, as it is depicted in FIG. 3. Since the magnetic fields 332, 334 are aligned opposite to each other, the influence field 336 can be determined by subtracting the two fields that were detected by means of sensors 110, 112.

It is possible to determine the position by means of subtracting the influence field 336 from the detected magnetic field [S1] of the first sensor 110. The same calculation is performed with the second sensor 112. Subsequently, the plausibility of the position is validated by means of the two detected values after they have been adjusted.

All of the used sensors 110, 112 serve for the detection of the position as well as for verification of the plausibility and are used simultaneously in order to determine the interference field 336.

Rod magnets 106, 108 are used in the embodiment depicted in FIG. 3, whereby an individual magnet 106, 108 is used for each sensor 110, 112, and where the fields 332, 334 influence the sensors 110, 112 in the opposite direction. Sensors 110, 112 are aligned in the same direction, so that the influence field 336 influences the sensors 110, 112 in the same way. According to a further embodiment, sensors 110, 112 are aligned orthogonally towards each other.

The movement of the transmitter device with the magnets 106, 108 is a 3D motion, whereby, for example, rod magnet 106 is tilted in relation to sensor 110, and is distanced from sensor 110. Accordingly, rod magnet 108 is tilted in relation to sensor 112, and is distanced from sensor 112.

According to an embodiment, magnets 106, 108 are located inside of a ball joint above sensors 110, 112, whereby the ball of the ball joint is turned around its center point by means of a selector lever, as it is depicted, for example, in FIG. 1.

FIG. 4 depicts an embodiment of a magnetic field sensor which corresponds to the embodiment that is described according to FIG. 3, where one horseshoe magnet 406 is used instead of two separate magnets. Thus, one horseshoe magnet 406 is used, consisting of only one pole pair, which interacts with at least two sensors 110, 112. A first shank of the horseshoe magnet 406, forming the first magnetic pole, for example, the north pole, is arranged opposite to the first sensor 110. A second shank of the horseshoe magnet 406, forming a second magnetic pole, for example, the south pole, is arranged opposite the second sensor 112.

FIGS. 5a to 5c show schematic depictions of a portion of a magnetic field sensor in different relative positions. In each case, magnet 106 is depicted, which is arranged in such a way that it can be moved in relation to a sensor 110. It could, for example, represent the first magnet 106 and the first sensor 110, which are depicted in FIG. 3. Magnet 106 can perform relative movements 540 in relation to sensor 110, as they are depicted by means of the arrows. These could be rotational movements or tilting movements, where a longitudinal axis of magnet 106 is inclined in relation to a surface of sensor 110. Hereby, a distance between the pole of magnet 106, which is facing sensor 110, and the center point of sensor 110 is changed.

FIG. 5a depicts the magnetic field sensor in a center position. The longitudinal axis of rod magnet 106 is arranged orthogonally to a scanning surface or to a base surface of sensor 110 in the center position. The longitudinal axis of magnet 106 runs through the center point of sensor 110. A center point of the pole of magnet 106 has the least distance to sensor 110 in the center position. In other positions, such as those depicted in FIGS. 5b and 5c, the center point of the pole of magnet 106 has a larger distance to sensor 110. Sensor 110 is penetrated by an almost homogeneous magnetic field, in which its magnetic field lines are aligned basically orthogonal to the scanning surface.

FIG. 5b depicts the magnetic field sensor in a position in which it is deflected in a first direction. In the position that is depicted in FIG. 5b, the longitudinal axis of rod magnet 106 is inclined at an angle towards the scanning surface or the base surface of sensor 110. Sensor 110 is penetrated by an almost homogeneous magnetic field, in which its magnetic field lines are aligned at an angle to the scanning surface or base surface.

FIG. 5c depicts the magnetic field sensor in a position in which it is deflected in a second direction, whereby the second direction is orthogonal to the first direction that is depicted in FIG. 5b. In the position that is depicted in FIG. 5c, the longitudinal axis of rod magnet 106 is inclined at an angle towards the scanning surface or the base surface of sensor 110. Sensor 110 is penetrated by an almost homogeneous magnetic field, in which its magnetic field lines are aligned in an angle to the scanning surface or base surface.

FIGS. 6a to 6c show schematic depictions of a further magnetic field sensor in different relative positions. The magnetic field sensor can, for example, be used in connection with the operating device that is shown in FIG. 1. In contrast to the embodiment that is depicted according to FIG. 3, instead of two magnets, only one magnet 106 is used in the transmitter device. Just like in the embodiment depicted in FIG. 3, the detecting device consists of two sensors 110, 112, but they are arranged in a different way.

Thus, the magnetic field sensor that is depicted in FIGS. 6a to 6c consists of a magnet 106, a first sensor 110 and a second sensor 112. The first sensor 110 and the second sensor 112 are arranged in a stacked order on opposing surfaces of a carrier 330, such as a conductor board or a circuit board. But sensors 110, 112 do not necessarily have to be mounted on a carrier such as a circuit board. Regarding their scanning direction, the first sensor 110 and the second sensor 112 are aligned in the opposite direction. This can be accomplished when two identical sensors 110, 112 are used, which are arranged in such a way that with regard to the magnet, the lower surface, for example the contacting surface, is once facing downwards and once upwards in a mirror inverted way. Thus, it is possible that contacting surfaces of sensors 110, 112 are facing each other. Magnet 106 can be moved relative to the sensors 110, 112.

Magnet 106 is arranged opposite to the stack made up of the first sensor 110 and of the second sensor 112. A pole of the first magnet 106, for example the north pole, is arranged opposite to the scanning surface or the base surface of the first sensor 110 and of the second sensor 112. Magnet 106 is designed in such a way, that it produces a magnetic field 332 which is detected by the first sensor 110 and by the second sensor 112. The magnetic field 332, which is detected by the first sensor 110 and by the second sensor 112, is dependent on the position of magnet 106 in relation to the first sensor 110 and the second sensor 112. Thus, by means of the respective magnetic field that is detected by means of the first sensor 110 and the second sensor 112, it is possible to determine a relative position between the first sensor 110 and magnet 106 as well as a relative position between the second sensor 112 and magnet 106. Magnet 106 and the first sensor 110 thus form a first measuring unit and magnet 106 and the second sensor 112 form a second measuring unit.

Sensors 110, 112 are arranged within a detection range that can be influenced by a magnetic influence field. The detection range can be selected so small that the magnetic influence field within the detection range is almost homogeneous, so that sensors 110, 112 are influenced by the same magnetic influence field.

FIG. 6a depicts a magnetic field sensor in a center position. In the center position, a longitudinal axis of magnet 106 is arranged orthogonally to a scanning surface or to a base surface of sensors 110, 112. Sensors 110, 112 are penetrated by an almost homogeneous magnetic field, in which its magnetic field lines are aligned basically orthogonal to the scanning surfaces.

FIG. 6b depicts the magnetic field sensor in a position in which it is deflected in a first direction. In the position that is depicted in FIG. 6b, the longitudinal axis of magnet 106 is inclined at an angle towards the scanning surfaces or the base surfaces of sensors 110, 112. Sensors 110, 112 are penetrated by an almost homogeneous magnetic field, in which its magnetic field lines are aligned at an angle to the scanning surfaces or base surfaces.

FIG. 6c depicts the magnetic field sensor in a position in which it is deflected into a second direction, whereby the second direction is orthogonal to the first direction that is depicted in FIG. 6b. In the position that is depicted in FIG. 6c, the longitudinal axis of magnet 106 is inclined at an angle towards the scanning surfaces or the base surfaces of sensors 110, 112. Sensors 110, 112 are penetrated by an almost homogeneous magnetic field, in which its magnetic field lines are aligned in an angle to the scanning surfaces or base surfaces.

According to an embodiment, FIGS. 6a to 6c depict a magnetic field sensor with a rod magnet 106. This is a variation to the arrangements that were described before. According to the arrangement that is depicted in the FIGS. 6a to 6c, one sensor 110 is positioned above, and one sensor 112 below the conductor board 330, respectively. Thus, a ball bearing mounted rod magnet 106, which is allocated above sensor 110 affects the upper sensor 110 in the opposite direction as it does the lower sensor 112. In this embodiment, one rod magnet 106 is sufficient for two or four sensors 110, 112. Four sensors 110, 112 lead to an increase in the availability. Hereby, sensors 110, 112 can be arranged in duplicated form, respectively.

The embodiments that are described and depicted in the figures are chosen as mere examples. It is possible that different embodiments are fully combined with each other, or only combined in regard to individual characteristics. It is also possible that an embodiment is supplemented by characteristics of a further embodiment. In addition to that, procedural steps of the embodiments can be repeated or also performed in a different sequence than in the way in which they are described.

If an embodiment consists of an “and/or” connection between a first characteristic and a second characteristic, then this can be understood in a way that the embodiment can include the first characteristic as well as the second characteristic in one embodiment, and only the first characteristic or only the second characteristic in another embodiment.

### REFERENCE SIGNS

102 first component
104 second component
106 first magnet
108 second magnet
110 first sensor
112 second sensor
114 evaluation device
220 step of producing a magnetic field
222 step of detecting a magnetic field
224 step of combining sensor signals
330 carrier
332 first magnetic field
334 second magnetic field
336 magnetic influence field
406 magnet
540 relative movement

1. A magnetic field sensor comprising:
a transmitter device with at least one magnet for producing a magnetic field,
a detecting device for detecting the magnetic field,
wherein the transmitter device and the detecting device are configured to move in relation to each other, and
wherein the detecting device comprises:
a first sensor for producing a first sensor signal which is dependent on the magnetic field, and
a second sensor for producing a second sensor signal which is dependent on the magnetic field,
wherein the first sensor and the second sensor are arranged next to each other within an extension of a longitudinal axis of a detection range of the at least one magnet.

2. A magnetic field sensor according to claim 1, further comprising an evaluation device that is designed to combine the first sensor signal and the second sensor signal in order to determine a magnetic disturbance which is superimposed onto the magnetic field.

3. A magnetic field sensor according to claim 1, wherein the first sensor and the second sensor are arranged such that the magnetic field that penetrates the first sensor has a different magnetic field direction than the magnetic field that penetrates the second sensor during operation of the magnet field sensor.

4. A magnetic field sensor according to claim 1, wherein the transmitter device is designed to produce a first magnetic field and a second magnetic field, wherein the first magnetic field and the second magnetic field are aligned in different directions,
wherein the first sensor is designed to produce the first sensor signal dependent on the first magnetic field and the second sensor is designed to produce the second sensor signal dependent on the second magnetic field, and
wherein a scanning direction of the first sensor corresponds to a scanning direction of the second sensor.

5. A magnetic field sensor according to claim 4, wherein the transmitter device includes a first magnet for producing the first magnetic field and a second magnet for producing the second magnetic field, wherein the second magnet is arranged next to the first magnet.

6. A magnetic field sensor according to claim 4, wherein the at least one magnet has a magnetic north pole for producing the first magnetic field and a magnetic south pole for producing the second magnetic field, wherein the first magnetic field and the second magnetic field can be sections of the at least one magnet's magnetic field that are located between the magnetic north pole and the magnetic south pole.

7. A magnetic field sensor according to claim 4, wherein the strengths of the first magnetic field and of the second magnetic field can be equal in their amount.

8. A magnetic field sensor according to claim 3, wherein the first sensor has a first scanning level and the second sensor has a second scanning level, and wherein the first sensor and the second sensor are arranged next to each other in the same scanning level.

9. A magnetic field sensor according to claim 1, wherein a scanning direction of the first sensor is aligned in the opposite direction to a scanning direction of the second sensor, wherein a magnetic field line of the magnetic field penetrates the first sensor as well as the second sensor during operation of the magnetic field sensor.

10. An operating device for a motor vehicle comprising:
a first component;
a second component, wherein the first component and the second component are configured to move in relation to each other, and
a magnetic field sensor comprising:
a transmitter device with at least one magnet for producing a magnetic field,
a detecting device for detecting the magnetic field, the detecting device comprising:
a first sensor for producing a first sensor signal which is dependent on the magnetic field, and
a second sensor for producing a second sensor signal which is dependent on the magnetic field, wherein the first sensor and the second sensor are arranged next to each other within an extension of a longitudinal axis of a detection range of the at least one magnet, and
wherein the transmitter device is arranged onto the first component and the detecting device is arranged onto the second component.

11. A method for determining a relative position between a first component and a second component, where the first component and the second component are arranged such that they can move in relation to each other, the method comprising:
producing a magnetic field with a transmitter device which is arranged on the first component, wherein the transmitter device includes at least one magnet for producing the magnetic field;
detecting the magnetic field with a detecting device which is arranged on the second component, wherein the detecting device comprises a first sensor for producing a first sensor signal which is dependent on the magnetic field and a second sensor for producing a second sensor signal which is dependent on the magnetic field, wherein the first sensor and the second sensor are arranged next to each other within an extension of a longitudinal axis of a detection range of the at least one magnet; and
combining the first sensor signal with the second sensor signal in order to determine the relative position between the first component and the second component.

12. A magnetic field sensor according to claim 1, further comprising an evaluation device that is designed to combine the first sensor signal and the second sensor signal in order to determine a parameter of the magnetic field.

13. A magnetic field sensor according to claim 1, further comprising an evaluation device that is designed to combine the first sensor signal and the second sensor signal in order to determine a relative position between the transmitter device and the detecting device.

14. A magnetic field sensor according to claim 1, further comprising an evaluation device that is designed to combine the first sensor signal and the second sensor signal in order to determine relative movement between the transmitter device and the detecting device.

15. A magnetic field sensor according to claim 1, further comprising an evaluation device that is designed to account for a magnetic influence field when determining a relative position between the transmitter device and the detecting device.

16. A magnetic field sensor according to claim 1, wherein the first sensor signal and the second sensor signal represent detection of the magnetic field.

17. A magnetic field sensor according to claim 1, wherein the first sensor signal and the second sensor signal represent a strength of the magnetic field.

18. A magnetic field sensor according to claim 1, wherein the first sensor signal and the second sensor signal represent a direction of the magnetic field.

19. A magnetic field sensor according to claim 1, wherein the first sensor has two different scanning levels, wherein the two different scanning levels of the first sensor are arranged orthogonally to each other, and
wherein the second sensor has two different scanning levels, wherein the two different scanning levels of the second sensor are arranged orthogonally to each other.

20. The operating device according to claim 10, wherein the first component is a selector lever for a motor vehicle transmission, and wherein the second component is the mounting structure for the selector lever.
